(19) United States
(12) Patent Application Publication
(10) Pub. No.: US 2017/0288097 A1
(43) Pub. Date: Oct. 5, 2017

(54) Display Device And Display Module

(71) Applicant: Wuhan China Star Optoelectronics Technology Co., Ltd., Wuhan (CN)

(72) Inventors: De-jiun LI, Shenzhen (CN); Haibo PENG, Shenzhen (CN); Lingyan CHEN, Shenzhen (CN)

(73) Assignee: Wuhan China Star Optoelectronics Technology Co., Ltd., Wuhan (CN)

(21) Appl. No.: 15/167,998

(22) Filed: May 28, 2016

(30) Foreign Application Priority Data
Apr. 5, 2016 (CN) 2016102080086

(51) Int. Cl. H01L 33/50; H01L 33/58; F21V 9/08

(52) U.S. Cl. CPC H01L 33/50; F21V 9/08; H01L 33/58

(57) ABSTRACT

A display device and a display module. The display module includes: a blue LED chip, a yellow phosphor layer and a colour filter. A peak wavelength of a blue light emitted from the blue LED chip is in a range of 460±5 nm. The blue LED chip excites the yellow phosphor layer to emit a white light. The colour filter is disposed outside the yellow phosphor layer, and the white light emitted irradiates on colour filter. Through right shifting the peak wavelength of the blue band emitted from the blue LED chip to about 460 nm to realize the low blue energy and decrease the radiation. The transmittance of blue light of the colour filter is less than 7%, the transmission peak wavelength of blue light is in a range of 440-450 nm. The display module can decrease the energy of the blue band and ensure the display effect.

### BACKGROUND OF THE INVENTION

### 1. Field of the Invention

The present invention relates to a technology field of display device backlight and light filtering, and more particularly to a display device and a display module.

### 2. Description of Related Art

In the lights emitted from the display device, unavoidably, more blue light is contained. Medical research indicates that the light in the blue band has a higher energy, and will cause the damage of the vision when the human eye contact chronically. The damage to the growing and developing people such as infants, young is more obvious in this aspect. The way to decrease the blue energy on the market is to attach a blue filter or decrease the blue energy through an APP (application). However, the drawback of the above method is that the display of the blue color will be distorted, and the whole picture will exist a serious yellow shift phenomenon, the display quality is dramatically decreased. Accordingly, how to maintain displaying a realistic color, and decrease the affection of the blue light to the human eye in order to achieve the effect of protecting the human eye is a major research topic in the display industry.

With reference to FIG. 1, FIG. 1 is a blue backlight spectrum of two phosphor materials commonly used in a backlight module of the conventional art. In FIG. 1, a horizontal axis represents different wavelengths (unit mm), a vertical axis represent an energy ratio. The medical science believes that the wavelength of the blue light less than 430 nm will be more harmful to the human eye. The LED backlight principle widely used currently is: a blue chip excites a yellow phosphor to emit a light. The type of the phosphor can be divided into Silicate and YAG (abbreviation of yttrium aluminum garnet, chemical formula Y₃Al₅O₁₂, which is a composite oxide produced by the reacting of Y₂O₃ and Al₂O₃, belong to cubic crystal system, having a garnet structure. The garnet cell can be deemed as network links of dodecahedron, octahedral and tetrahedral) type. In FIG. 1, the numeral 1 is a blue spectrum of a Silicate phosphor material, and the numeral 2 is a blue spectrum of a YAG phosphor material. The blue chip adopting the Silicate phosphor material or the YAG material has a common point: an energy peak of the blue band is at a wavelength about 447 nm, and the energy is mainly concentrated below 450 nm. Because the visible light emitted by the backlight has a higher energy at the blue band, the low blue damage of the display device becomes a problem that cannot be ignored.

### SUMMARY OF THE INVENTION

The embodiment of the present invention provides a display device and a display module in order to solve the technology problem that is conflicting between decreasing the low blue damage and the display effect of the conventional art.

In order to solve the above problem, the embodiment of the present invention provides a display module, wherein the display module comprises: a blue LED chip, a peak wavelength of a blue light emitted from the blue LED chip is in a range of 460±5 nm; a yellow phosphor layer, wherein the blue LED chip excites the yellow phosphor layer to emit a white light; and a colour filter disposed outside the yellow phosphor layer, and the white light emitted from the yellow phosphor layer is irradiated on the colour filter.

According to a preferred embodiment of the present invention, the peak wavelength of the blue light emitted from the blue LED chip is in a range of 460±2 nm.

According to a preferred embodiment of the present invention, the peak wavelength of the blue light emitted from the blue LED chip is 460 nm.

According to a preferred embodiment of the present invention, a red phosphor is added into the yellow phosphor layer.

According to a preferred embodiment of the present invention, a red phosphor is added into the yellow phosphor layer.

According to a preferred embodiment of the present invention, a transmittance of blue light of the colour filter is less than 5%.

According to a preferred embodiment of the present invention, a transmission peak wavelength of blue light of the colour filter is in a range of 440˜450 nm

According to a preferred embodiment of the present invention, a transmission peak wavelength of blue light of the colour filter is 445 nm.

In order to solve the above technology problem, the embodiment of the present invention also provides a display device, wherein, the display device includes anyone of the display module of the above embodiments.

Comparing to the conventional art, in the display module provided by the present invention, through right shifting the peak wavelength of the blue wave band emitted from the blue LED chip to about 460 nm in order to realize the low blue energy so as to decrease the radiation. At the same time, in order to not decrease the display effect (generally including color saturation, NTSC color gamut and if the color is shifted and so on), designing a colour filter, the transmittance of the blue light of the colour filter is less than 7%, the peak wavelength of the blue light is in a range of 440-450 nm. The display module cannot only decrease the energy of the blue wave band, but also ensure the display effect, Besides, the display module also adds a certain amount of red phosphors in order to make the energy distribution ratios of red/green/blue three colors of the emission light emitted from the display device to closer, that is, closed to the natural light.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a blue backlight spectrum of two phosphor materials commonly used in a backlight module of the conventional art;

FIG. 2 is a comparison diagram of spectrum of blue backlight between the present invention and the conventional art;

FIG. 3 is a schematic comparison diagram of blue energy less than 430 nm in the spectrum diagram in FIG. 2; and

FIG. 4 is a schematic structure diagram of a preferred embodiment of a display device of the present invention.

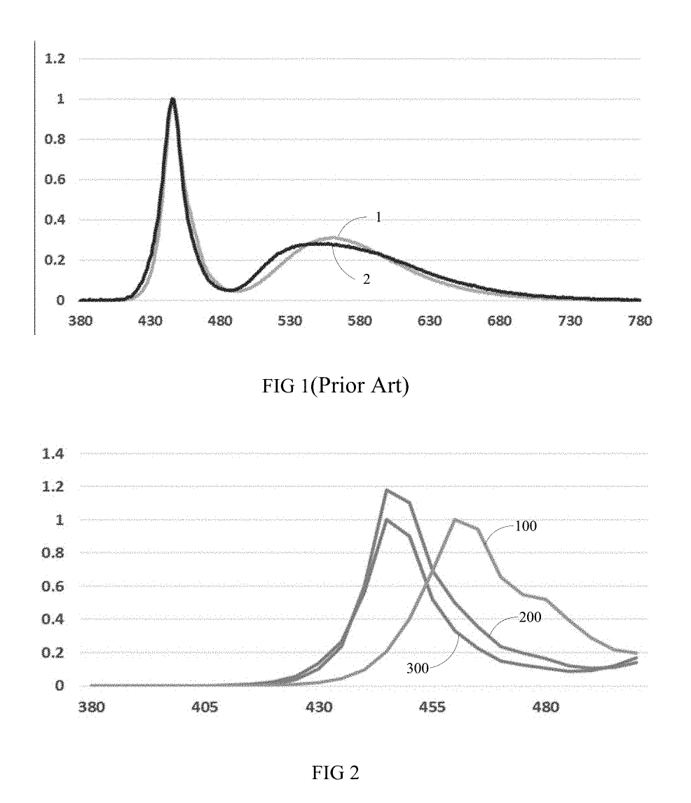

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

The embodiment of the present invention provides a display module, and the display module includes a blue LED chip, a yellow phosphor layer and a colour filter. Wherein, in order to decrease the energy of the blue light emitted from the blue LED chip, the embodiment of the present invention right shifts a peak wavelength of the blue light emitted from the blue LED chip, adjusting to about 460 nm. Preferably, the peak wavelength of the blue light emitted from the blue LED chip is in a range of 460±5 nm. Preferably, the peak wavelength of the blue light emitted from the blue LED chip is in a range of 460±2 nm, or the peak wavelength of the blue light emitted from the blue LED chip is 460 nm.

The yellow phosphor layer is disposed on a surface of the blue LED chip or above the surface of the blue LED chip. The blue LED chip excites the yellow phosphor layer to emit a white light. The colour filter is disposed outside the yellow phosphor layer, and the white light emitted from the yellow phosphor layer is irradiated on the colour filter.

Right shifting the peak wavelength of the blue light emitted from the blue LED chip can realize a low blue energy. However, the problem is that: when obtaining the low blue energy effect at the same time, the color will obviously deviate, the color saturation of NTSC (NTSC means National Television Standards Committee) will obviously decrease. With reference to Table 1, Table 1 is a comparison of performance parameters between parameters of standard chromaticity diagram sRGB (standard Red Green Blue) and a low energy blue backlight BL (backlight) matching with a conventional CF (colour filter).

| | RED | | GREEN | | BLUE | | White | | |
|---|---|---|---|---|---|---|---|---|---|
| Sim-No | x | y | x | y | x | y | x | y | NTSC |
| sRGB Target | 0.640 | 0.330 | 0.300 | 0.600 | 0.150 | 0.060 | 0.300 | 0.320 | 70.8% |
| Low blue BL + | 0.634 | 0.338 | 0.302 | 0.578 | 0.142 | 0.066 | 0.332 | 0.344 | 65.9% |
| conventional CF | | | | | | | | | |

Through above comparison, comparing the color performance of utilizing the above design (the peak wavelength of blue light is right shifted) BL matching with the conventional CF to a target sRGB color system, the W (white) and G (green) colors are obviously shifted, and the color saturation of NTSC is also obviously decreased.

The BL (backlight) matching with the peak wavelength of the blue light right shifted (to about 460 nm), when realizing the low blue energy at the same time, in order to make the color to be not shifted. The method utilized is: designing a new CF (colour filter) that has a different transmission spectrum comparing to the conventional art, and after the colour filter matching with the BL that the peak wavelength of the blue light is right shifted (to about 460 nm), the sRGB display effect can be realized, that is the preferred display effect. As shown in Table 2, Table 2 is a comparison of display performance parameters of a display device among the above three situations.

| | RED | | GREEN | | BLUE | | White | | |
|---|---|---|---|---|---|---|---|---|---|
| Sim-No | x | y | x | y | x | y | x | y | NTSC |
| sRGB Target | 0.640 | 0.330 | 0.300 | 0.600 | 0.150 | 0.060 | 0.300 | 0.320 | 70.8% |
| Low blue BL + | 0.634 | 0.338 | 0.302 | 0.578 | 0.142 | 0.066 | 0.332 | 0.344 | 65.9% |
| conventional CF | | | | | | | | | |
| Low blue BL + | 0.639 | 0.332 | 0.301 | 0.605 | 0.154 | 0.060 | 0.299 | 0.317 | 70.8% |
| invented special CF | | | | | | | | | |

The difference between the present embodiment CF and the CF in the conventional art is mainly at B (Blue light), in the technology solution of the present application, after matching with the BL that the peak wavelength of the blue light is right shifted, CF_B (the colour filter to the blue light) should be decreased in the transmittance, and the transmission peak wavelength of the CF_B should be shifted to left, that is, to be decreased in order to balance the affection of the color because of the change of the BL (right shifted to about 460 nm). Requirement of the preferred range: if the transmittance of a conventional CF_B is 9.99%, and the transmission peak wavelength of the blue light is in a range of 460˜470 nm, then, the transmittance of CF_B in the present embodiment should be adjusted to be less than 7%, and the transmission peak wavelength of the blue light should be adjusted to in a range of 440˜450 nm. More preferably, if the transmittance of CF_B should be adjusted to be decreased less than 5%, the transmission peak wavelength of blue light of the colour filter should be adjusted to 445 nm or around 445 nm. There are many methods that utilize a photoresist to adjust the transmittance and the transmission peak wavelength such as adjusting a ratio of the color and the transparent material in the photoresist and so on. The way to adjust the transmittance and the transmission peak wavelength is under the scope that can be understood by person skilled in the art, no more repeating here.

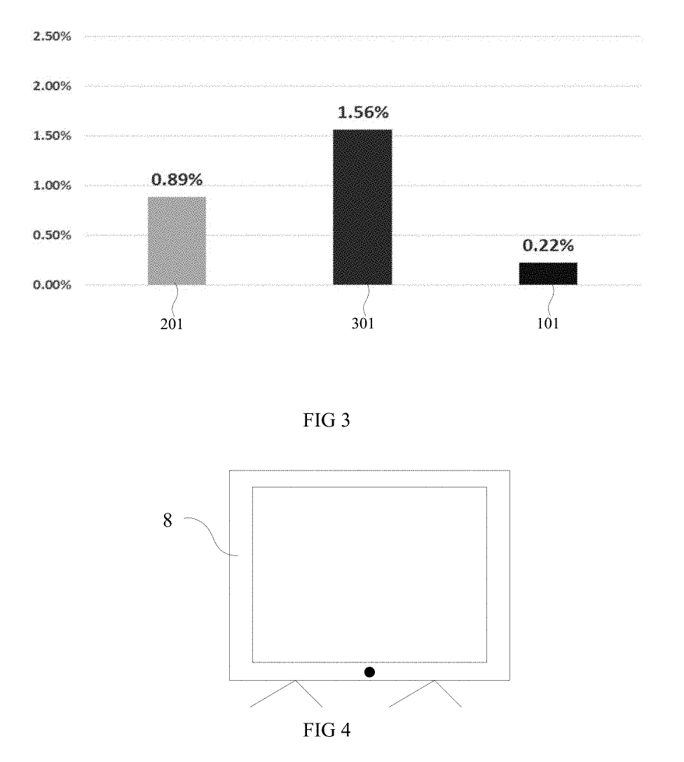

With combined reference to FIG. 2 and FIG. 3, wherein FIG. 2 is a comparison diagram of spectrum of blue backlight between the present invention and the conventional art. In FIG. 2, the horizontal axis represents different wavelength (unit: nm), and the vertical axis represents energy ratio. The numeral 200 represents the blue spectrum of the Silicate phosphor material, the numeral 300 represents the blue spectrum of the YAG phosphor material, and the numeral 100 represents the blue spectrum of the technology solution of the present invention. FIG. 3 is a schematic comparison diagram of the blue energy less than 430 nm in the diagram of spectrum in FIG. 2. In FIG. 3, the numeral 201 is a blue energy column of the Silicate phosphor material, the numeral 301 is a blue energy column of the YAG phosphor material, and the numeral 101 is a blue energy column of the technology solution of the present invention. Obviously shown in the figure, the backlight (BL) using the conventional Silicate phosphor material, the blue energy less than 430 nm is 0.89%; the backlight (BL) using the conventional YAG phosphor material, the blue energy less than 430 nm is 1.56%; and the backlight (BL) using the technology solution of the present embodiment is decreased to 0.22%. Even comparing to the backlight (BL) using the conventional Silicate phosphor material, the decrease degree of the energy is up to 75%.

Furthermore and preferably, in order to make the energy distribution of the visible light (wavelength range 380˜780 nm) emitted by the display device to be closer to a mode of a natural light, a red phosphor is added into the yellow phosphor layer adopted in the embodiment of the present invention. The purpose is to make energy distribution ratios of red/green/blue three colors emitted by the display device to be closer, that is, closer to a natural light.

Because the natural light is a continuous light and different wavelength energies are closed, utilizing the new display module can improve the above in this aspect. With reference to Table. 3, and Table. 3 is a comparison table of energy of red, green and blue three wave bands of display modules of three structures.

| RGB energy analysis | | R | G | B |
|---|---|---|---|---|
| Normal_Silicate | Peak | 605 | 550 | 445 |
| BL | ±20 nm Ratio | 16.14% | 25.96% | 28.19% |
| Normal_YAG | Peak | 605 | 550 | 445 |
| BL | ±20 nm Ratio | 16.56% | 22.46% | 27.29% |
| Low Blue BL | Peak | 585 | 535 | 460 |
| | ±20 nm Ratio | 27.13% | 22.77% | 29.71% |

From the above data, the conventional LED BL utilizing a normal Silicate or YAG phosphor, the energy relationship of the red, green and blue three wave bands of the display device is B>>G>>R; in comparison, in the technology solution of the present application: B≈R>G, which is closer to the display effect of the natural light.

Comparing to the conventional art, in the display module provided by the present invention, through right shifting the peak wavelength of the blue wave band emitted from the blue LED chip to about 460 nm in order to realize the low blue energy so as to decrease the radiation. At the same time, in order to not decrease the display effect (generally including color saturation, NTSC color gamut and if the color is shifted and so on), designing a colour filter, the transmittance of the blue light of the colour filter is less than 7%, the peak wavelength of the blue light is in a range of 440-450 nm. The display module cannot only decrease the energy of the blue wave band, but also ensure the display effect, Besides, the display module also adds a certain amount of red phosphors in order to make the energy distribution ratios of red/green/blue three colors of the emission light emitted from the display device to closer, that is, closed to the natural light.

In addition, the embodiment of the present invention also provides a display device. With reference to FIG. 4, and FIG. 4 is a schematic structure diagram of a preferred embodiment of a display device of the present invention. Wherein, the display device includes a case 8 and the display modules in the above embodiments disposed inside the case 8. The technology features of the display module can refer to the detailed description in the above embodiment, and the technology features of the other structures of the display device are under the scope that can be understood by person skilled in the art, no more repeating here.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A display module, wherein the display module comprises:
a blue LED chip, a peak wavelength of a blue light emitted from the blue LED chip is in a range of 460±5 nm;
a yellow phosphor layer, wherein the blue LED chip excites the yellow phosphor layer to emit a white light; and
a colour filter disposed outside the yellow phosphor layer, and the white light emitted from the yellow phosphor layer is irradiated on the colour filter.

2. The display module according to claim 1, wherein the peak wavelength of the blue light emitted from the blue LED chip is in a range of 460±2 nm.

3. The display module according to claim 2, wherein, the peak wavelength of the blue light emitted from the blue LED chip is 460 nm.

4. The display module according to claim 2, wherein, a red phosphor is added into the yellow phosphor layer.

5. The display module according to claim 4, wherein, a red phosphor is added into the yellow phosphor layer.

6. The display module according to claim 5, wherein, a transmittance of blue light of the colour filter is less than 5%.

7. The display module according to claim 5, wherein, a transmission peak wavelength of blue light of the colour filter is in a range of 440˜450 nm.

8. The display module according to claim 7, wherein, a transmission peak wavelength of blue light of the colour filter is 445 nm.

9. A display device, wherein, the display device includes a display module, and the display module comprises:
a blue LED chip, a peak wavelength of a blue light emitted from the blue LED chip is in a range of 460±5 nm;
a yellow phosphor layer, wherein the blue LED chip excites the yellow phosphor layer to emit a white light; and
a colour filter disposed outside the yellow phosphor layer, and the white light emitted from the yellow phosphor layer is irradiated on the colour filter.

10. The display device according to claim 9, wherein the peak wavelength of the blue light emitted from the blue LED chip is in a range of 460±2 nm.

11. The display device according to claim 10, wherein, the peak wavelength of the blue light emitted from the blue LED chip is 460 nm.

12. The display device according to claim 9, wherein, a red phosphor is added into the yellow phosphor layer.

13. The display device according to claim 12, wherein, a red phosphor is added into the yellow phosphor layer.

14. The display device according to claim 13, wherein, a transmittance of blue light of the colour filter is less than 5%.

15. The display device according to claim 13, wherein, a transmission peak wavelength of blue light of the colour filter is in a range of 440˜450 nm.

16. The display device according to claim 15, wherein, a transmission peak wavelength of blue light of the colour filter is 445 nm.
